(19) United States
(12) Patent Application Publication
(10) Pub. No.: US 2016/0071948 A1
(43) Pub. Date: Mar. 10, 2016

(54) Non-Volatile Memory Device and Method for Manufacturing Same

(71) Applicant: Kabushiki Kaisha Toshiba, Tokyo (JP)

(72) Inventors: Kenichiro TORATANI, Yokkaichi (JP); Masayuki TANAKA, Yokkaichi (JP); Takashi FURUHASHI, Yokkaichi (JP)

(73) Assignee: Kabushiki Kaisha Toshiba

(21) Appl. No.: 14/636,338

(22) Filed: Mar. 3, 2015

Related U.S. Application Data
(60) Provisional application No. 62/047,831, filed on Sep. 9, 2014.

(51) Int. Cl. H01L 29/51; H01L 21/28; H01L 27/115

(52) U.S. Cl. CPC H01L 29/517; H01L 27/11517; H01L 21/28273

(57) ABSTRACT

According to a nonvolatile memory device including a semiconductor layer, a control electrode, a memory layer provided between the semiconductor layer and the control electrode, a first insulating film provided between the semiconductor layer and the memory layer, and a second insulating film provided between the control electrode and the memory layer. The second insulating film includes a metal oxide having a monoclinic structure.

### CROSS-REFERENCE TO RELATED APPLICATIONS

This application is based upon and claims the benefit of priority from U.S. Provisional Patent Application 62/047,831 filed on Sep. 9, 2014; the entire contents of which are incorporated herein by reference.

### FIELD

Embodiments are generally related to a non-volatile memory device and a method for manufacturing the same.

### BACKGROUND

A NAND type nonvolatile memory device comprises a memory cell including a semiconductor layer, a charge storage layer, and a control electrode. Programming data to the memory cell and erasing data in the memory cell are performed to change the amount of charge inside the charge storage layer by applying a bias between the semiconductor layer and the control electrode. In such a nonvolatile memory device, it is important to reduce the leakage current of the tunneling insulating film provided between the semiconductor layer and the charge storage layer, and the leakage current of the blocking insulating film provided between the charge storage layer and the control electrode in order to improve the programming and erasing characteristics of the data as well as improve the data retention characteristics. However, it may become difficult to suppress the leakage current of the blocking insulating film, since the blocking insulating film is going to be thinner in memory cells that are downscaled to increase the memory capacity.

### BRIEF DESCRIPTION OF THE DRAWINGS

FIG. 1 is an exemplary view schematically showing a non-volatile memory device according to a first embodiment;

FIGS. 2A and 2B are exemplary cross-sectional views schematically showing a memory cell according to the first embodiment;

FIGS. 3A to 4B are cross-sectional views schematically showing a manufacturing process of the memory cell according to the first embodiment;

FIGS. 5 and 6 are graphs showing characteristics of block insulating film according to the first embodiment;

FIGS. 7A and 7B are exemplary cross-sectional views schematically showing a memory cell according to a first variation of the first embodiment;

FIGS. 8A and 8B are exemplary cross-sectional views schematically showing a memory cell according to a second variation of the first embodiment;

FIGS. 9A and 9B are exemplary cross-sectional views schematically showing a memory cell according to a third variation of the first embodiment;

FIG. 10 is exemplary cross-sectional view schematically showing a memory cell according to a fourth variation of the first embodiment;

FIG. 11 is an exemplary perspective view schematically showing a non-volatile memory device according to a second embodiment; and

FIG. 12 is an exemplary cross-sectional view schematically showing a memory cell according to the second embodiment.

### DETAILED DESCRIPTION

According to a nonvolatile memory device including a semiconductor layer, a control electrode, a memory layer provided between the semiconductor layer and the control electrode, a first insulating film provided between the semiconductor layer and the memory layer, and a second insulating film provided between the control electrode and the memory layer. The second insulating film includes a metal oxide having a monoclinic structure.

Embodiments will now be described with reference to the drawings. The same portions inside the drawings are marked with the same numerals; a detailed description is omitted as appropriate; and different portions are described. The drawings are schematic or conceptual; and the relationships between the thicknesses and widths of portions, the proportions of sizes between portions, etc., are not necessarily the same as the actual values thereof. Also, the dimensions and/or the proportions may be illustrated differently between the drawings, even in the case where the same portion is illustrated.

Further, the disposition and configuration of each portion is described using an X-axis, a Y-axis, and a Z-axis shown in the drawings. The X-axis, the Y-axis, and the Z-axis are orthogonal to each other and represent an X-direction, a Y-direction, and a Z-direction, respectively. Also, there are cases where the Z-direction is described as upward and the direction opposite to the Z-direction is described as downward.

### First Embodiment

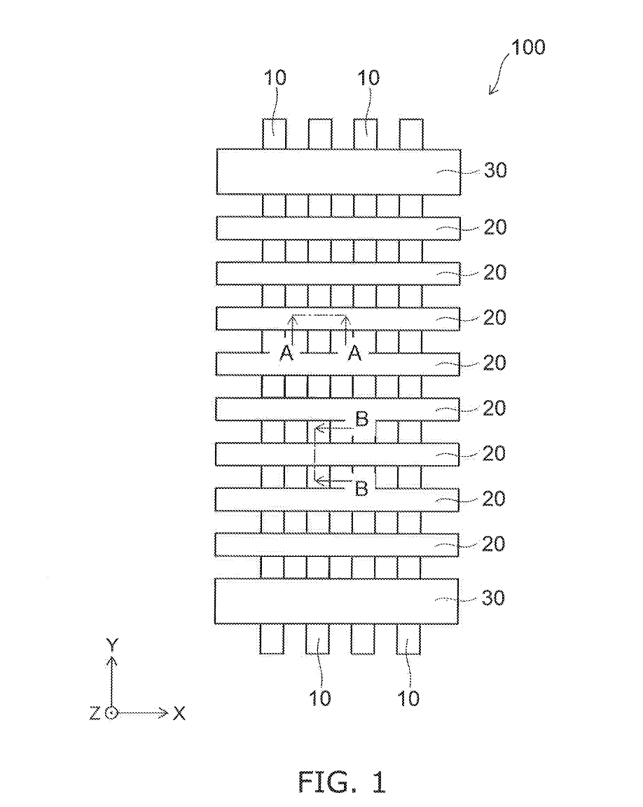

FIG. 1 is a schematic view showing a nonvolatile memory device 100 according to a first embodiment. The nonvolatile memory device 100 is, for example, NAND flash memory.

As shown in FIG. 1, the nonvolatile memory device 100 includes multiple semiconductor layers 10. The semiconductor layers 10 are arranged in the X-direction and each provided in a stripe shape extending in the Y-direction. For example, the semiconductor layers 10 are provided on a semiconductor substrate.

The nonvolatile memory device 100 includes multiple word lines 20 and selection gates 30. The word lines 20 and the selection gates 30 are provided in stripe configurations; and the word lines 20 and the selection gates 30 extend in the X-direction on the multiple semiconductor layers 10. The word lines 20 are arranged in the Y-direction. The selection gates 30 are disposed on two sides of the multiple word lines 20 arranged in the Y-direction.

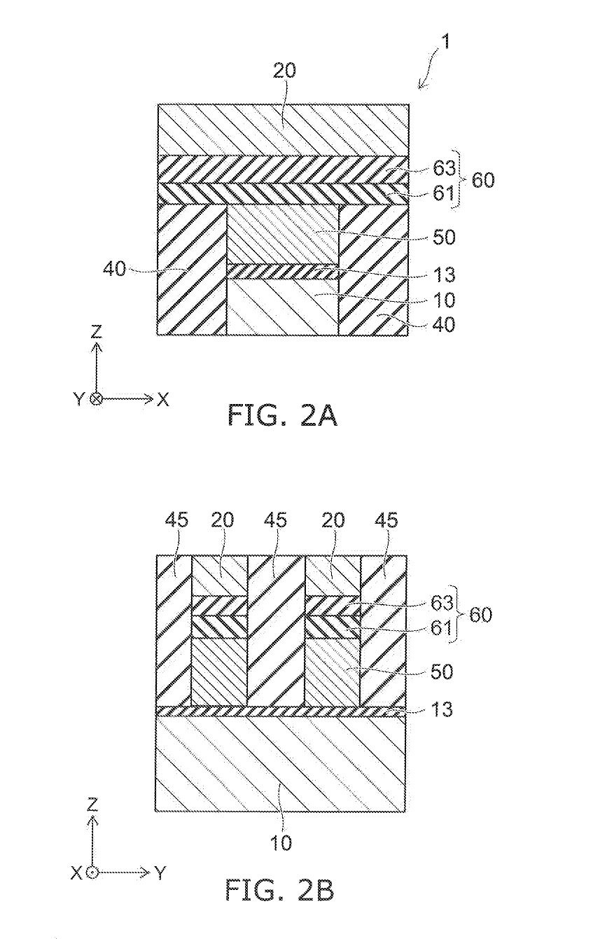

FIGS. 2A and 2B are schematic cross-sectional views showing a memory cell 1 according to the first embodiment. FIG. 2A shows a cross section along line A-A shown in FIG. 1. FIG. 2B shows a cross section along line B-B shown in FIG. 1.

As shown in FIG. 2A, the nonvolatile memory device 100 includes a charge storage layer 50 at the portion where the word line 20 crosses the semiconductor layer 10. The charge storage layer 50 acts as a memory layer of the memory cell 1.

A tunneling insulating film 13 is provided between the semiconductor layer 10 and the charge storage layer 50. Also, a blocking insulating film 60 is provided between the word line 20 and the charge storage layer 50. In the example, the blocking insulating film 60 has a stacked structure including a first film 61 and a second film 63.

For example, a trench-type insulating region that is a so-called a STI (Shallow Trench Insulation) 40 is provided between semiconductor layers 10 adjacent to each other in the X-direction. The STI 40 is, for example, a silicon oxide film and electrically insulates the semiconductor layers 10 adjacent to each other in the X-direction. Also, the STI 40 electrically insulates the charge storage layers 50 adjacent to each other in the X-direction.

As shown in FIG. 2B, multiple charge storage layers 50 are arranged in the Y-direction on the semiconductor layers 10. Also, the charge storage layers 50 are disposed between the semiconductor layers 10 and the word lines 20. In other words, the nonvolatile memory device 100 includes the memory cells 1 at the portions where the word lines 20 crosses the semiconductor layers 10; and the memory cells 1 include the charge storage layers 50.

The tunneling insulating films 13 are, for example, silicon oxide films and are formed to cover the front surfaces of the semiconductor layers 10. An inter-layer insulating film 45 is provided between the charge storage layers 50 adjacent to each other in the Y-direction and between the word lines 20 adjacent to each other in the Y-direction. The inter-layer insulating film 45 is, for example, a silicon oxide film and electrically insulates between the word lines 20 and between the charge storage layers 50.

The word line 20 acts as a control electrode of the memory cell 1. When programming data to the memory cell 1 or erasing data in the memory cell 1, a bias is applied between the word line 20 and the semiconductor layer 10. Thereby, for example, electrons are injected into the charge storage layer 50 via the tunneling insulating film 13, or electrons are discharged from the charge storage layer 50 via the tunneling insulating film 13. Also, when reading the data, the memory cell 1 acts as a memory cell transistor; and the word line 20 controls the ON and OFF of the electrical conduction in the channel formed in the interface between the semiconductor layer 10 and the tunneling insulating film 13.

To suppress the leakage current of the blocking insulating film 60 in the memory cell 1 having such operations, for example, it is desirable to reduce the bias applied between the semiconductor layer 10 and the word line 20. To this end, it is favorable to increase the ratio that is a so-called coupling ratio of the capacitance between the word line 20 and the charge storage layer 50 and the capacitance between the semiconductor layer 10 and the charge storage layer 50. For example, the coupling ratio can be increased by the blocking insulating film 60 including a metal oxide film having a high relative dielectric constant.

For example, an oxide film including at least one element of silicon (Si), aluminum (Al), magnesium (Mg), yttrium (Y), hafnium (Hf), zirconium (Zr), or lanthanum (La) may be used as such a metal oxide film. Also, a nitride film or an oxynitride film including one of the elements recited above may be used in place of the metal oxide file.

The charge storage layer 50 may be, for example, a FG (Floating Gate) layer, or may have a MONOS (Metal Oxide Nitride Oxide Semiconductor) type structure. In other words, the charge storage layer 50 can include, for example, conductive polysilicon or a metal. Also, the charge storage layer 50 may be an insulating layer having an energy bandgap smaller than that of the tunneling insulating film 13. The charge storage layer 50 may include, for example, silicon nitride.

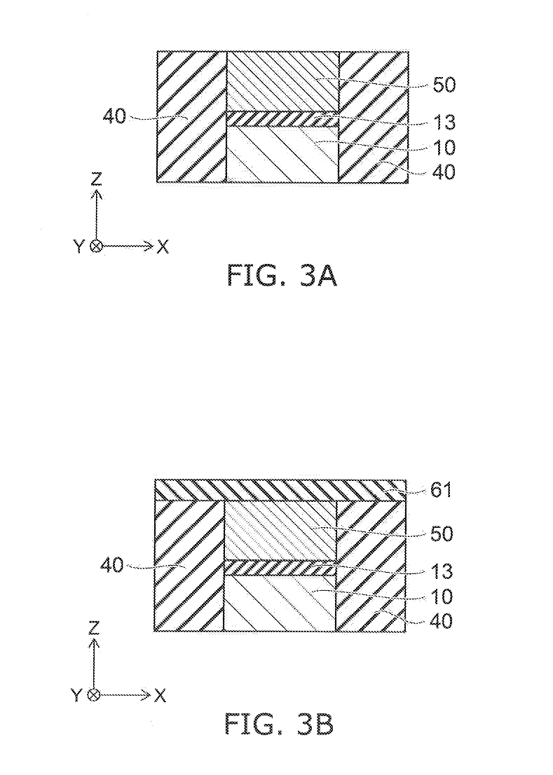

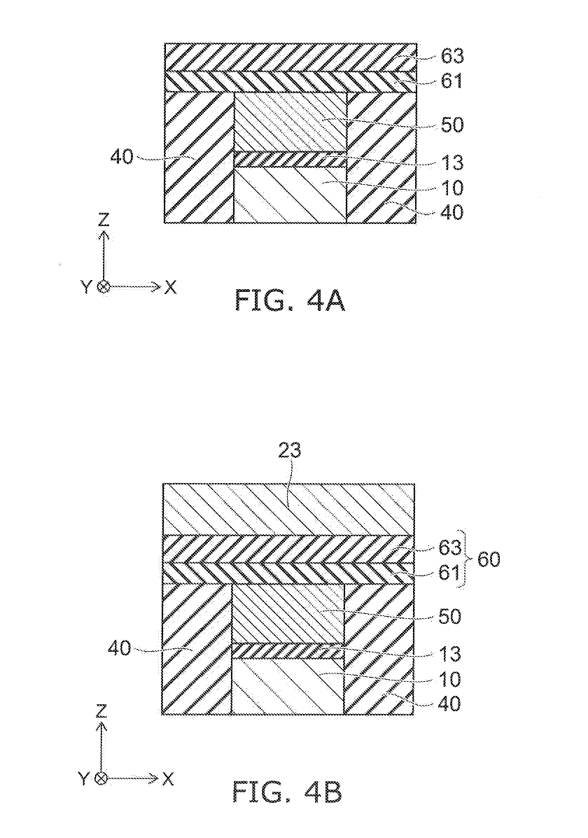

FIGS. 3A to 4B are schematic cross-sectional views showing manufacturing processes of the memory cell 1 according to the first embodiment. FIGS. 3A to 4B correspond to the A-A cross section of FIG. 1.

As shown in FIG. 3A, a wafer including semiconductor layers 10 is prepared, in which the tunneling insulating film 13 and the charge storage layer 50 are formed on the semiconductor layer 10. The STI 40 is formed between the charge storage layers 50 and between the semiconductor layers 10 adjacent to each other in the X-direction.

The semiconductor layer 10 is, for example, a region having a stripe configuration formed on a p-type silicon substrate. Also, the semiconductor layer 10 may be formed in a p-type well provided on an n-type silicon substrate by etching the p-type well into a stripe configuration.

The tunneling insulating film 13 is a silicon oxide film having a thickness of 1 nanometer (nm) to 10 nm formed on the semiconductor layer 10. The charge storage layer 50 is, for example, a polysilicon layer having a thickness of 1 nm to 50 nm formed by chemical vapor deposition on the tunneling insulating film 13.

Specifically, for example, the tunneling insulating film 13 and the charge storage layer 50 are formed in order on the p-type silicon substrate. Then, trenches having stripe configurations are made from the front surface of the charge storage layer 50 to reach the p-type silicon substrate; and a silicon oxide film is filled into the trenches to form the STI 40. Thereby, a wafer having the structure shown in FIG. 3A can be formed.

Then, as shown in FIG. 3B, the first film 61 is formed on the charge storage layer 50 and the STI 40. The first film 61 is, for example, a hafnium oxide film (WO) having a thickness of 1 nm to 10 nm. Favorably, the thickness of the first film 61 is set to be 3.5 nm or less. Thereby, the impurity inside the film can be reduced effectively.

For example, the hafnium oxide film is formed using atomic layer deposition (ALD), Tetrakis-ethylmethylamino-hafnium (TEMAH) is used as the hafnium source; and ozone is used as the oxidizing agent. The film formation temperature is, for example, 300° C. In the ALD, the film can be formed by atomic layer units by multiply repeating the sequence of supplying an active gas such as ozone, etc., purging by vacuum evacuation, supplying a metal source gas, purging by vacuum evacuation, and resupplying the active gas such as ozone, etc.

In the embodiment, the method for forming the hafnium oxide film is not limited to ALD, and may be, for example, chemical vapor deposition (CVD), physical vapor deposition (PVD) using physical excitation, sputtering, coating, etc. Also, the source of the hafnium is not limited to TEMAH and may be, for example, a material such as another amino compound in which an alkyl group other than an ethyl methyl group is bonded, hafnium halide, etc. The oxidizing agent may include water, oxygen, or another material such as an oxygen radical, etc.

Heat treatment is performed after forming the first film 61. For example, the hafnium oxide is amorphous, which is formed using the ALD. For example, the hafnium oxide is crystallized through the heat treatment by heating to 650° C. or more.

Then, as shown in FIG. 4A, the second film 63 is formed on the first film 61 after the heat treatment. The second film 63 is, for example, a hafnium oxide film having a thickness of 1 nm to 10 nm. For example, the second film 63 is formed using ALD. Then, the hafnium oxide in the second film 63 is also crystallized through another heat treatment after forming the second film 63.

The second film 63 is not limited to a hafnium oxide film and may be an oxide of another metallic element. Also, in the case where the second film 63 is an oxide of the same metallic element as the first film 61, the blocking insulating film 60 may be formed to have a structure in which the first film 61 and the second film 63 are joined to be one body.

Then, as shown in FIG. 4B, a conductive film 23 that is used to form the word line 20 is formed on the second film 63. The conductive film 23 is, for example, a conductive polysilicon film. Also, the conductive film 23 may be, for example, a tungsten (W) film having a thickness of 10 nm to 50 nm. Further, the conductive film 23 may have, for example, a two-layer structure including tungsten (W) and titanium nitride (TiN), wherein the titanium nitride is in contact with the second film 63.

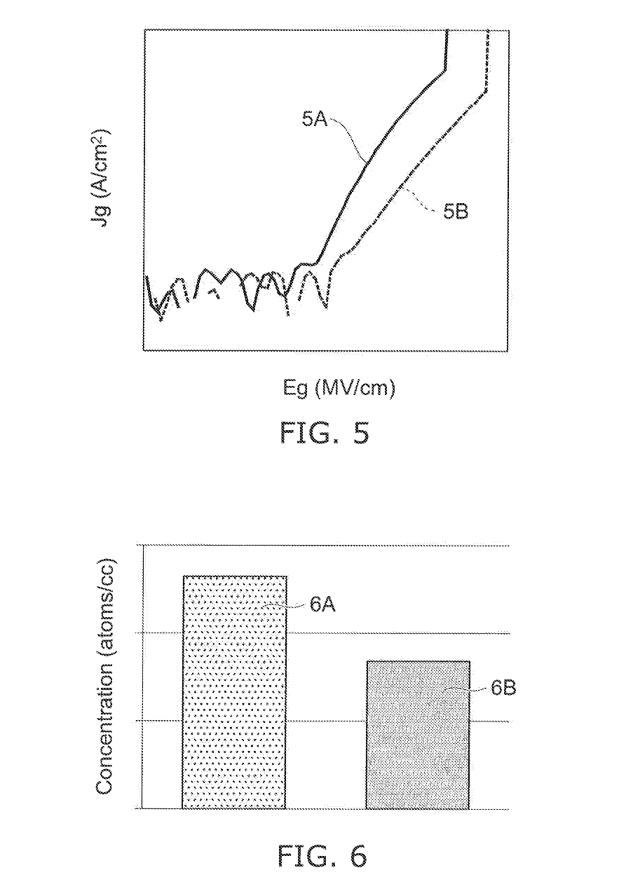

FIG. 5 is a graph of the leakage current of the blocking insulating film 60 according to the first embodiment. The vertical axis is a leakage current density Jg; and the horizontal axis is an electric field Eg of the blocking insulating film 60. 5B shown in FIG. 5 is a leakage current characteristic of the blocking insulating film 60 according to the embodiment. On the other hand, 5A is a leakage current characteristic of a blocking insulating film according to a comparative example. The blocking insulating film according to the comparative example is a film of hafnium oxide continuously grown to a prescribed thickness. In other words, the hafnium oxide film is thicker than the blocking insulating film 60; and heat treatment is performed after the hafnium oxide film is formed as the blocking insulating film.

As shown in FIG. 5, the leakage current density Jg starts to flow when a certain electric field Eg is exceeded. Also, the leakage current in the blocking insulating film 60 according to the embodiment is suppressed to be lower than that of the blocking insulating film according to the comparative example.

FIG. 6 is a graph of impurity concentrations inside the films. The impurity concentrations of the blocking insulating film 60 according to the embodiment and the blocking insulating film according to the comparative example are compared. For example, carbon (C) is assimilated into the film and becomes an impurity in the case where an organic source is used as the metal source. As shown in FIG. 6, an impurity concentration 6B of the blocking insulating film 60 according to the embodiment is lower than an impurity concentration 6A of the blocking insulating film according to the comparative example.

Thus, in the embodiment, the blocking insulating film 60 is not formed continuously, but is formed by dividing into the first film 61 and the second film 63. Then, the concentration of the impurity atoms included in the film can be reduced by the heat treatment after forming the first film 61. Thereby, it is possible to suppress the leakage current.

The number of layers included in the blocking insulating film is not limited to that of the example recited above. Namely, the blocking insulating film may have a stacked structure including three or more layers. Also, the leakage current can be suppressed by reducing the impurity concentration inside the film by performing heat treatment for each layer.

Also, for example, the blocking insulating film includes a monoclinic metal oxide. In other words, in a thick blocking insulating film which includes a continuously grown metal oxide, the metal oxide may have a crystal structure of a high atomic density such as cubic, tetragonal, orthorhombic, and the like after the heat treatment. In contrast, the blocking insulating film 60 includes subdivided layers each formed in the individual steps, and the thickness of each layer is thin. Hence, for example, the metal oxide becomes monoclinic in the first film 61, not becoming cubic, tetragonal, or orthorhombic. Also, the metal oxide becomes monoclinic in the second film 63, which is formed on the first film 61 having the monoclinic crystal structure, since inheriting the crystal structure of the underlying layer. Such a crystal structure can be confirmed by using, for example, XRD (X-ray Diffraction), a TEM (Transmission Electron Microscope), and the like.

In other words, the leakage current can be reduced by reducing the impurity in the film even without the blocking insulating film 60 having the crystal structure of a high atomic density such as cubic, tetragonal, orthorhombic, and the like. Also, in such a case, it is sufficient for the heat treatment after the film formation to be at a temperature that can reduce the impurities in the film; and the heat treatment after the film formation may be implemented at a temperature lower than the temperature at which the amorphous metal oxide is crystallized.

By using the manufacturing method recited above, it becomes possible to reduce the film thickness of the blocking insulating film 60; and it may be possible to achieve further downscaling of the memory cell. In a memory cell that includes the blocking insulating film 60 recited above, for example, the charge injection in the erasing from the word line 20 is suppressed; and the erasing speed may be increased. While programming and retaining the data, the charge leakage to the word line 20 can be suppressed. Also, it is possible to increase the programming speed of data.

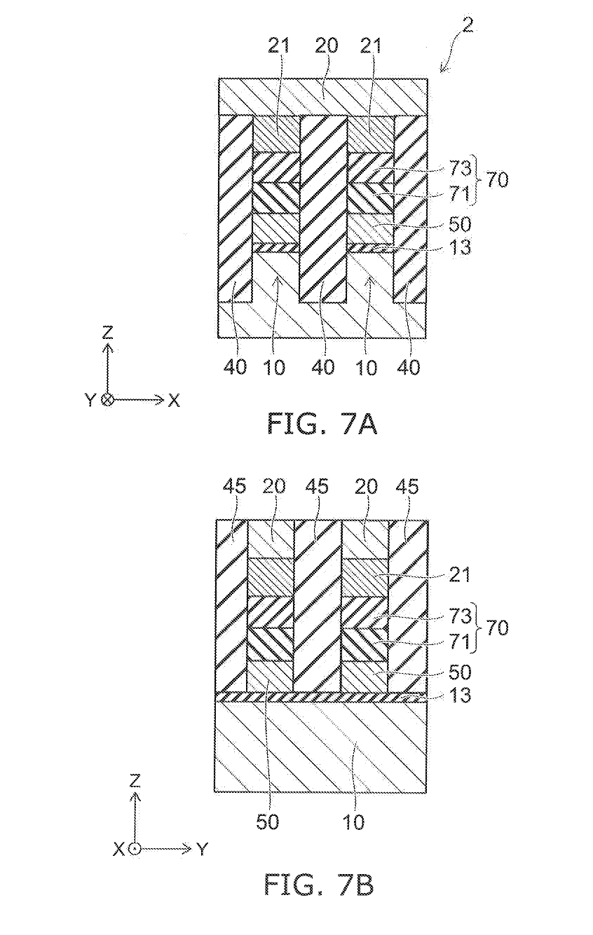

FIGS. 7A and 7B are schematic cross-sectional views showing a memory cell 2 according to a first variation of the first embodiment. FIG. 7A shows the cross section along line A-A shown in FIG. 1. FIG. 7B shows the cross section along line B-B shown in FIG. 1.

As shown in FIG. 7A, the memory cell 2 includes the tunneling insulating film 13, the charge storage layer 50, a blocking insulating film 70, and a control electrode 21. These elements are disposed between the semiconductor layer 10 and the word line 20. The blocking insulating film 70 has a stacked structure including a first film 71 and a second film 73.

The blocking insulating film 70 is a metal oxide film, for example, a hafnium oxide film. In the formation processes of the blocking insulating film 70, heat treatment is performed after the formation of the first film 71; and another heat treatment is performed after the formation of the second film 73.

In the example, the STI 40 electrically isolates the charge storage layers 50 adjacent to each other in the X-direction. Further, the STI 40 isolates the blocking insulating films 70 in the X-direction. Also, as shown in FIG. 7B, the charge storage layer 50 and the blocking insulating film 70 are isolated by the inter-layer insulating film 45 in the Y-direction. Thereby, the charge movement via the blocking insulating film can be suppressed between the charge storage layers 50 adjacent to each other in the X-direction and the Y-direction.

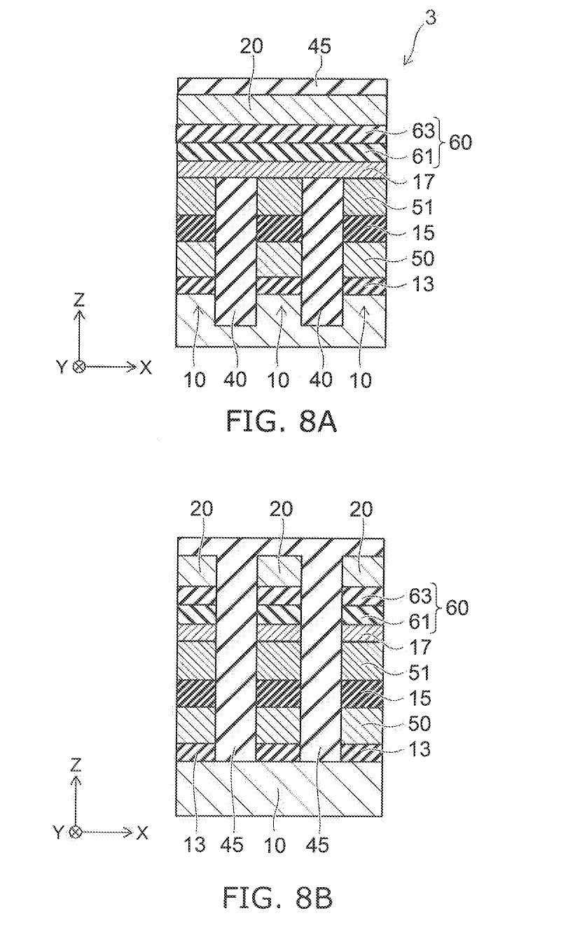

FIG. 8 is a schematic cross-sectional view showing a memory cell 3 according to a second variation of the first embodiment. FIG. 8A shows the cross section along line A-A shown in FIG. 1. FIG. 8B shows the cross section along line B-B shown in FIG. 1.

As shown in FIG. 8A, the memory cell 3 includes the tunneling insulating film 13, the charge storage layer 50, an intermediate insulating film (Inter-facial Dielectric: IFD) 15, and a charge trap film 51 provided in order on the semiconductor layer 10. The tunneling insulating film 13, the charge storage layer 50, the IFD 15, and the charge trap film 51 are electrically insulated by the STI 40 in the X-direction. The memory cell 3 further includes a barrier film 17 for blocking metal diffusion, the blocking insulating film 60, and the word line 20 provided on the charge trap film 51 and the STI 40.

As shown in FIG. 8B, the tunneling insulating film 13, the charge storage layer 50, the IFD 15, the charge trap film 51, the barrier film 17, the blocking insulating film 60, and the word line 20 are electrically insulated by the inter-layer insulating film 45 in the Y-direction. In the example, the inter-layer insulating film 45 is formed to cover the stacked body recited above provided on the semiconductor layer 10.

The charge storage layer 50 is, for example, a FG-type layer. The charge storage layer 50 is, for example, a conductive polysilicon layer. The charge trap film 51 may be a metal layer, for example. The barrier film 17 suppresses the diffusion of metal atoms from the charge trap film 51 into the blocking insulating film 60. The barrier film 17 is, for example, a silicon nitride film.

The blocking insulating film 60 has a stacked structure including the first film 61 and the second film 63. The number of layers included in the blocking insulating film 60 may be three or more. Then, heat treatment is performed after forming each layer.

The charge storage layer 50 and the charge trap film 51 that are included in the memory cell 3 may increase the programming efficiency of the data. Also, the charge trap film 51 may improve the charge retention characteristics by trapping the charge moving from the charge storage layer 50 across the IFD 15.

Further, the blocking insulating film 60 having the stacked structure may suppresses the leakage current that flows between the word line 20 and the charge trap film 51. It may be possible to reduce the film thickness of the blocking insulating film 60 without increasing the leakage current, and thus, to achieve the downscaling of the memory cell 3.

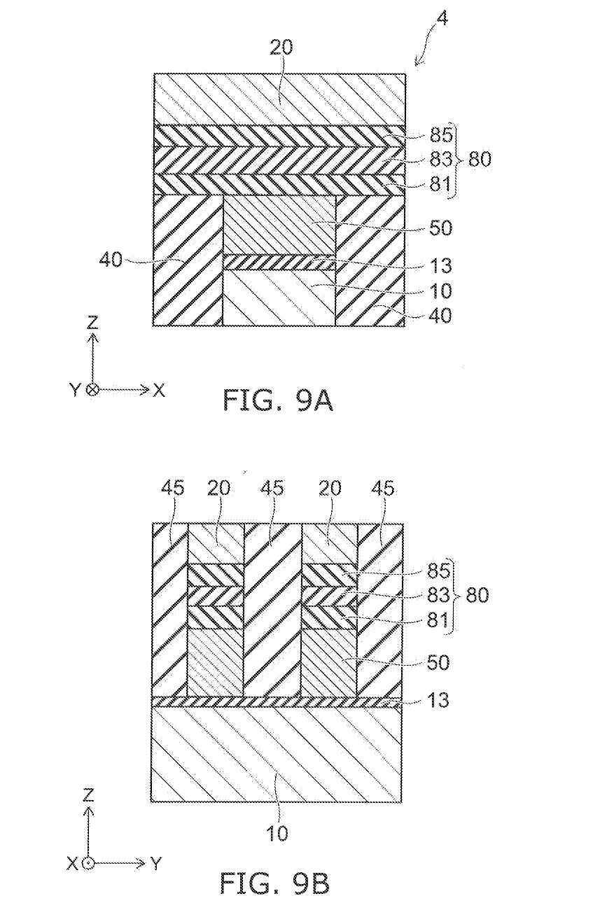

FIGS. 9A and 9B are schematic cross-sectional views showing a memory cell 4 according to a third variation of the first embodiment. FIG. 9A shows the cross section along line A-A shown in FIG. 1. FIG. 9B shows the cross section along line B-B shown in FIG. 1.

As shown in FIG. 9A, the memory cell 4 includes the tunneling insulating film 13, the charge storage layer 50, and a blocking insulating film 80 between the semiconductor layer 10 and the word line 20. The blocking insulating film 80 has a stacked structure including a first film 81, a second film 83, and a third film 85.

The STI 40 is provided between the semiconductor layers 10 adjacent to each other in the X-direction. The STI 40 electrically insulates the semiconductor layers 10 adjacent to each other in the X-direction. Also, the STI 40 electrically insulates the charge storage layers 50 adjacent to each other in the X-direction.

As shown in FIG. 9B, the multiple charge storage layers 50 are arranged in the Y-direction on the semiconductor layer 10. The inter-layer insulating film 45 is provided between the charge storage layers 50 and between the word lines 20 adjacent to each other in the Y-direction.

In the blocking insulating film 80, the first film 81 and the third film 85 include oxides of the same metallic element. The first film 81 and the third film 85 are, for example, hafnium oxide. The second film 83 is, for example, a metal oxide film to which silicon is added. The second film 83 may be an aluminum oxide film to which silicon is added, for example.

The aluminum oxide film to which silicon is added can be formed by, for example, ALD. Tri-methyl aluminum (TMA) is used as the aluminum source. Tris-dimethylamino-silane (TDMAS) is used as the silicon source; and ozone is used as the oxidizing agent. The film formation temperature is, for example, 300° C. The aluminum oxide film having the desired silicon content ratio may be formed by controlling the proportion of the silicon source to the aluminum source.

Although it is favorable to perform heat treatment after each step of forming the first film 81, the second film 83, and the third film 85, the embodiment is not limited thereto. For example, the heat treatment may be performed after stacking the first film 81, the second film 83, and the third film 85. Also, each of the first film 81, the second film 83, and the third film 85 may have a stacked structure of multiple films; and heat treatment may be performed after depositing each film included in the stacked structure.

For the aluminum oxide film, it is possible to reduce the leakage current by adding silicon to the film. It is favorable for the silicon amount added to the aluminum oxide film to be, for example, not less than 1 atomic % and not more than 10 atomic %. In the case where the content ratio of silicon is increased, the dielectric constant decreases; and the coupling ratio may become small. On the other hand, the advantage of suppressing the leakage current may be drastically dissipated when the content ratio of silicon is 1 atomic % or less.

In the case where the suppression of the leakage current is given priority over the coupling ratio, the content ratio of silicon can be increased to about 40 atomic %. For example, the dielectric constant of aluminum oxide containing 40 atomic % of silicon is about 7. Also, the blocking insulating film 80 may have a structure, in which the first film 81 and the third film 85 include metal oxide films having relative dielectric constants greater than 7, wherein the second film 83 acts to suppress the leakage current.

It may be also possible to reduce the electrical effective film thickness by using a material having a high dielectric constant for the first film 81 and the third film 85, thereby increasing the coupling ratio of the memory cell 4. Such materials are, for example, aluminum oxide (Al₂O₃) which has a dielectric constant of about 8, magnesium oxide (MgO) which has a relative dielectric constant of about 10, yttrium oxide (Y₂O₃) which has a relative dielectric constant of about 16, hafnium oxide (HfO₂) which has relative dielectric constants of about 22, zirconium oxide (ZrO₂) and lanthanum oxide (La₂O₃).

Also, the first film 81 and the third film 85 may be oxynitrides or nitrides having relative dielectric constants greater than 7. An oxide or an oxynitride may also be used, which includes at least one element of silicon (Si), aluminum (Al), magnesium (Mg), yttrium (Y), hafnium (Hf), zirconium (Zr), or lanthanum (La).

For example, the first film 81 may be formed to include charge traps in the case where the first film 81 is a hafnium oxide film. Thus, for example, when improving the data programming efficiency, it is favorable to make the first film 81 thicker than the second film 83. On the other hand, when the reduction of the leakage current is given priority in the blocking insulating film 80, it is favorable to make the first film 81 thinner than the second film 83. The second film 83 may have a film thickness of 1 nm to 10 nm, for example.

The first film 81 and the second film 83 may include a silicon oxide film or a silicon nitride film instead of a metal oxide. In such a case, the silicon oxide film or silicon nitride film reduce defects and impurities in the blocking insulating film. Thereby, it is possible to advantageously reduce the low electric field leakage of the blocking insulating film 80, and to improve the charge retention characteristics of the memory cell 4.

For example, the first film 81 and the second film 83 include at least one of such metal oxides. A ternary metal oxide that includes at least two kinds of metallic elements may preferably used for the second film 83. For example, hafnium silicate (HfSiO) and hafnium aluminate (HfAlO) may be used for the second film 83 other than the aluminum silicate (AlSiO) recited above.

The metallic element that is included in the first film 81 may be different from the metallic element that is included in the third film 85. Alternatively, the first film 81 and the third film 85 may include aluminum oxide to which silicon is added; and the second film 83 may include a silicon oxide film or a silicon nitride film. Further, the first film 81 and the third film 85 may include aluminum oxide to which silicon is added; and the second film 83 may include a hafnium oxide film. Also, a silicon oxide film or a silicon nitride film may be formed between the first film 81 and the second film 83 and/or between the second film 83 and the third film 85. Such a film structure may be used for the insulating films in other portions of the nonvolatile memory device 100, not being limited to the blocking insulating film 80.

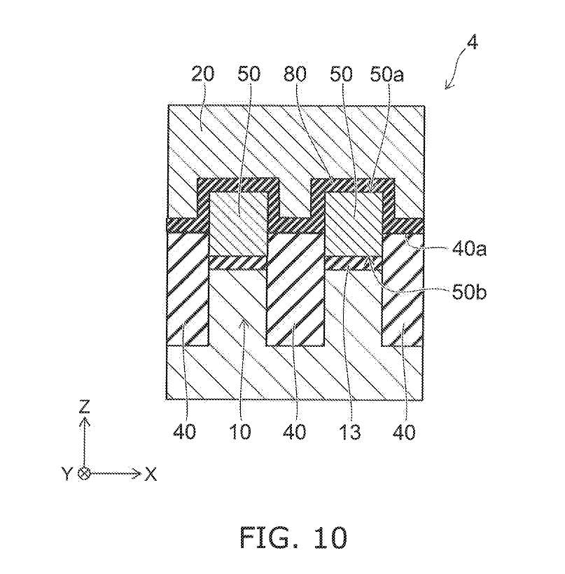

FIG. 10 is a schematic cross-sectional view showing a memory cell 5 according to a fourth variation of the first embodiment. FIG. 10 shows the cross section along line A-A shown in FIG. 1.

As shown in FIG. 10, the memory cell 5 includes the tunneling insulating film 13, the charge storage layer 50, and the blocking insulating film 80, which are disposed between the semiconductor layer 10 and the word line 20. The blocking insulating film 80 has the stacked structure including the first film 81, the second film 83, and the third film 85 as shown in FIG. 9A. The blocking insulating film 80 has the structure that reduces the leakage current recited above; and thus, it is possible to reduce the film thickness of the blocking insulating film 80.

In the example, an upper surface 40a of the STI 40 is positioned at a level between an upper surface 50a and a lower surface 50b of the charge storage layer 50 in the Z-direction. The blocking insulating film 80 covers a portion of the upper surface and side surface of the charge storage layer 50. It is possible to reduce the film thickness of the blocking insulating film 80; and such a structure also makes it possible to achieve downscaling of a memory cell.

As recited above, it is possible to reduce the leakage current in the blocking insulating films 60, 70, and 80 according to the embodiment. The leakage current value is reduced under both cases such as the high electric field when programming and erasing the data, and the low electric field when retaining the charge are reduced, thus exhibiting the desired device characteristics. From another viewpoint, it is possible to reduce the film thicknesses of the blocking insulating films 60, 70, and 80, thereby advantageously downscaling the memory cell. Also, the blocking insulating films 60, 70, and 80 are also advantageous for increasing the coupling ratio of the memory cell. Further, the blocking insulating films 60, 70, and 80 according to the embodiment are applicable to both a FG-type memory cell and a MONOS-type memory cell.

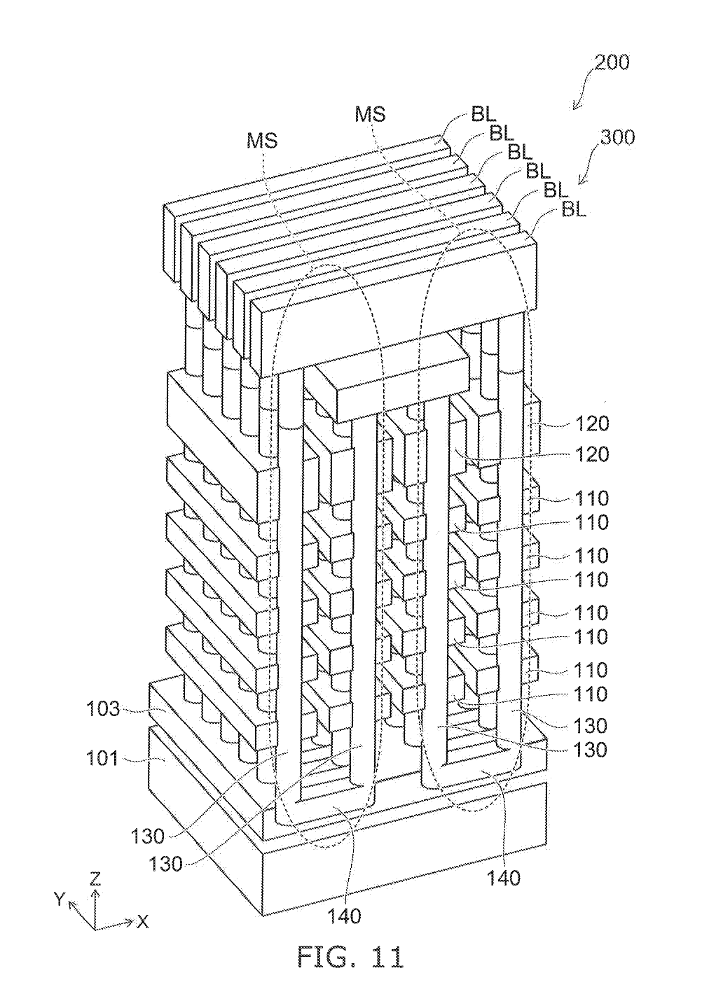

FIG. 11 is a perspective view schematically showing a nonvolatile memory device 200 according to a second embodiment. The nonvolatile memory device 200 includes a memory cell array having a three-dimensional structure.

As shown in FIG. 11, the nonvolatile memory device 200 includes, for example, a memory cell array 300 provided on a silicon substrate 101 with a back gate layer 103 interposed. The memory cell array 300 includes multiple word lines 110 and selection gates 120 stacked in the Z-direction. Also, the word lines 110 and the selection gates 120 are arranged in the X-direction. Further, the memory cell array 300 includes semiconductor pillars 130 extending through the word lines 110 and the selection gates 120 stacked in the Z-direction.

For example, two semiconductor pillars 130 that are adjacent to each other in the X-direction are connected by a pipe connection (PC) 140 in the back gate layer 103. Then, one end of the semiconductor pillars 130 joined via the PC 140 is electrically connected to a bit line BL. Also, the other end of the semiconductor pillars 130 is electrically connected to a source line SL.

Memory cells 6 are formed at the portions where the semiconductor pillars 130 and each of the word lines 110 cross. Also, selection transistors are formed between the selection gates 120 and the semiconductor pillars 130. Thereby, a memory string MS is formed along the two mutually-adjacent semiconductor pillars 130.

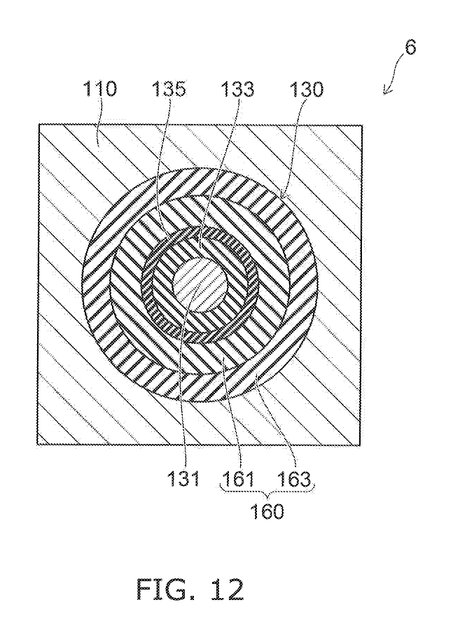

FIG. 12 is a schematic cross-sectional view showing the memory cell 6 according to the second embodiment. FIG. 12 is a schematic view showing a cross section of the semiconductor pillar 130 perpendicular to the Z-direction.

As shown in FIG. 12, the semiconductor pillar 130 includes a semiconductor layer 131, a tunneling insulating film 133, a charge storage layer 135, and a blocking insulating film 160. The semiconductor layer 131 extends in the Z-direction. The tunneling insulating film 133, the charge storage layer 135, and the blocking insulating film 160 also are formed to extend in the Z-direction along the semiconductor layer 131.

The memory cell 6 includes the tunneling insulating film 133, the charge storage layer 135, and the blocking insulating film 160, which are disposed between the word line 110 and the semiconductor layer 131. The blocking insulating film 160 includes a first film 161 and a second film 163. The blocking insulating film 160 is a metal oxide film. The first film 161 and the second film 163 are, for example, hafnium oxide films. The embodiment is not limited thereto; and, for example, the aluminum oxide film to which Si is added may also be used as described in the third variation and the fourth variation.

For example, the blocking insulating film 160 is formed on the inner surface of a memory hole extending through the multiple word lines 110 stacked in the Z-direction. Also, the second film 163 is formed on the inner surface of the memory hole; and the first film 161 is formed on the second film 163 in the processes of forming the blocking insulating film 160. Then, heat treatment is performed after the second film 163 is formed; and another heat treatment is further performed after the first film 161 is formed. Thereby, a blocking insulating film 160 may be formed in which the leakage current is suppressed.

Further, the charge storage layer 135, the tunneling insulating film 133, and the semiconductor layer 131 are formed in order on the blocking insulating film 160. Thereby, the memory cells 6 are provided between the semiconductor layer 131 and each of the word lines 110.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device, comprising:
a semiconductor layer;
a control electrode;
a memory layer provided between the semiconductor layer and the control electrode;
a first insulating film provided between the semiconductor layer and the memory layer; and
a second insulating film provided between the control electrode and the memory layer, the second insulating film including a metal oxide having a monoclinic structure.

2. The device according to claim 1, wherein the metal oxide film includes at least one element of silicon, aluminum, magnesium, yttrium, hafnium, zirconium and lanthanum.

3. The device according to claim 1, wherein the metal oxide film does not include a metal oxide having a cubic crystal structure, a tetragonal structure, or an orthorhombic structure.

4. The device according to claim 1, wherein the second insulating film has a stacked structure including a plurality of metal oxide films.

5. The device according to claim 4, wherein the plurality of metal oxide films includes a first film and a second film, the first film covering the memory layer, and the second film being provided on the first film, and
the first film includes the same metallic element as the second film.

6. The device according to claim 4, wherein
the plurality of metal oxide films includes a first film and a second film, the first film covering the memory layer, and the second film being provided on the first film, and
the first film includes a metallic el different from a metallic element of the second film.

7. The device according to claim 1, wherein the memory layer includes a conductive layer.

8. The device according to claim 1, wherein the memory layer includes an insulator having an energy bandgap narrower than an energy bandgap of the first insulating film.

9. The device according to claim 1, wherein
the memory layer includes a charge storage layer, a charge trap film, and a third insulating film, and
the third insulating film is provided between the charge storage layer and the charge trap film.

10. The device according to claim 9, wherein
the charge storage layer is conductive, and the charge trap film is a metal film.

11. A nonvolatile memory device, comprising:
a semiconductor layer;
a control electrode;
a memory layer provided between the semiconductor layer and the control electrode;
a first insulating film provided between the semiconductor layer and the memory layer; and
a second insulating film provided between the control electrode and the memory layer, the second insulating film including a first film provided on the memory layer side, a third film provided on the control electrode side, and a second film provided between the first film and the third film,
the second film being a metal oxide film that includes at least two kinds of metallic element, and
the first film and the third film being metal oxide films that include a metallic element other than aluminum.

12. The device according to claim 11, wherein the second film contains silicon atoms, and a silicon content ratio of the second film is 1 atomic percent or more.

13. The device according to claim 11, wherein the first film includes the same metallic element as the third film.

14. The device according to claim 11, wherein the first film and the second film include at least one of silicon, aluminum, magnesium, yttrium, hafnium, zirconium, or lanthanum.

15. A method for manufacturing a nonvolatile memory device, comprising:
stacking a first insulating film and a memory layer in order on a semiconductor layer;
forming a first film including a metal oxide on the memory layer;
heating the first film;
forming a second film including a metal oxide on the first film;
heating the second film; and
forming a conductive film on the second film.

16. The method according to claim 15, wherein each of the first film and the second film includes at least one of silicon, aluminum, magnesium, yttrium, hafnium, zirconium, or lanthanum.

17. The method according to claim 15, wherein the second film includes the same metallic element as the first film.

18. The method according to claim 15, wherein the second film includes a metallic element different from the first film.

19. The method according to claim 15, wherein the first film and the second film are heated at a temperature under which the metal oxides of the first and second films are crystallized to be a monoclinic structure.

20. The method for manufacturing the nonvolatile memory device according to claim 15,
forming at least one metal oxide film on the second film; and
heating the one metal oxide film after heating the first film and the second film respectively.
